(19) United States
(12) Patent Application Publication
(10) Pub. No.: US 2025/0349481 A1
(43) Pub. Date: Nov. 13, 2025

(54) SWITCHING APPARATUS FOR ELECTRICAL SYSTEMS AND DIAGNOSTIC METHOD FOR MONITORING SWITCHING APPARATUS OPERATION

(71) Applicant: ABB Scchweiz AG, Beden (CH)

(72) Inventors: Massimiliano Villano, Dalmine (BG) (IT); Carlo Taborelli, venegono Inferiore (VA) (IT)

(21) Appl. No.: 19/068,385

(22) Filed: Mar. 3, 2025

(30) Foreign Application Priority Data
May 9, 2024 (EP) 24175067.8

(51) Int. Cl. H01H 50/16; H01H 47/00; H01H 50/54

(52) U.S. Cl. CPC H01H 50/16; H01H 47/002; H01H 50/546

(57) ABSTRACT

A switching apparatus for electrical applications comprising one or more switch poles; with, for each switch pole, one or more fixed contacts and one or more movable contacts. The movable contacts are reversibly movable between an uncoupled position, at which said movable contacts are decoupled from said fixed contacts, and a coupled position, at which said movable contacts are coupled with said fixed contacts. The switching apparatus further comprises an actuation assembly operatively coupled to said movable contacts and including an electromagnetic actuator. The switching apparatus includes or is operatively coupled to a control unit for controlling the functionalities of the switching apparatus. Such a control unit is adapted to carry out a diagnostic method to monitor the operation of the switching apparatus during a switching maneuver.

### CROSS-REFERENCE TO RELATED APPLICATIONS

The present application claims priority to European Patent Application No. 24175067.8 filed on May 9, 2024, and titled “SWITCHING APPARATUS FOR ELECTRICAL SYSTEMS AND DIAGNOSTIC METHOD THEREOF”, which is hereby incorporated by reference in its entirety.

### TECHNICAL FIELD

The present disclosure concerns a switching apparatus for electrical systems, such as a circuit breaker, a contactor, a disconnector, or the like. More specifically, the present disclosure relates to a switching apparatus of the electromagnetic type, which is particularly adapted for installation in medium voltage electrical systems.

### BACKGROUND

Switching apparatuses of the electromagnetic type are widely used in electrical systems, particularly in electric grids or switchgears operating at medium voltage levels.

In general, these devices represent an important improvement with respect to most traditional mechanical switching apparatuses. However, wear phenomena of the electric contacts, changes in operational conditions of the motion transmission components, deterioration phenomena in the electromagnetic actuator, and the like may have a strong influence on their performances. Monitoring the performances of these devices, particularly during their switching maneuver, is therefore quite important to prevent faults and timely plan maintenance interventions.

A traditional approach to collect diagnostic information about the operation of a switching apparatus of the electromagnetic type consists in arranging a number of sensors to monitor the behavior of the most critical components of the switch poles. However, these sensing arrangements often entail an increase of the overall size of the switch poles and higher manufacturing costs. They can thus be difficult and expensive to implement at industrial level.

EP3460822A1 discloses a more recent diagnostic method to check the operating conditions of a switching apparatus of electromagnetic type. Such a diagnostic method provides for using a mathematical model of the electromagnetic actuator to reconstruct the travel waveforms of the movable contacts of the switch poles based on the observation of the waveforms of the voltage and current applied to the electromagnetic actuator.

This solution provides relevant advantages as it allows avoiding the installation of dedicated sensors to monitor the behavior of the switching apparatus. Additionally, it allows collecting accurate diagnostic information about anomalies during the switching maneuver. This diagnostic approach, however, requires performant computational resources for being implemented in practice. Therefore, it may be difficult to execute at local level, for example by a control unit mounted on-board the switching apparatus.

In the state of the art, it is quite felt the need for innovative solutions that allow overcoming or mitigating the above-evidenced limitations and drawbacks of the currently available solutions.

### BRIEF DESCRIPTION

In a general definition, the switching apparatus of the present disclosure comprises one or more switch poles, with, for each switch pole, one or more fixed contacts and one or more movable contacts. The movable contacts are reversibly movable between an uncoupled position, at which said movable contacts are decoupled from said fixed contacts, and a coupled position, at which said movable contacts are coupled with said fixed contacts. The switching apparatus further comprises an actuation assembly operatively coupled to said movable contacts and including an electromagnetic actuator.

The switching apparatus includes or is operatively coupled to a control unit for controlling the functionalities of the switching apparatus.

Such a control unit is adapted to carry out a diagnostic method to monitor the operation of the switching apparatus during a switching maneuver.

The diagnostic method comprises the following activities: acquiring detection signals indicative of one or more electrical quantities related to the operation of said switching apparatus, during a switching maneuver of said switching apparatus; based on said detection signals, calculating, for each electrical quantity, a diagnostic waveform indicative of an actual behavior of said electrical quantity, during a switching maneuver of said switching apparatus; selecting a timing parameter to be calculated in relation to a switching maneuver of said switching apparatus; selecting a diagnostic waveform and an observation time window to calculate the selected timing parameter; determining a perturbation instant in the selected diagnostic waveform during the selected observation time window; and calculating the selected timing parameter based on the determined perturbation instant.

In some embodiments, the above-mentioned one or more electrical quantities include at least one between a voltage feeding said electromagnetic actuator; and an excitation current feeding said electromagnetic actuator.

According to certain embodiments of the present disclosure, the above-mentioned activity of determining said perturbation instant comprises calculating a first checking value indicative of the derivative over time of the selected diagnostic waveform during the selected observation time window; comparing said first checking value within a predefined first threshold value; and determining said perturbation instant as an instant, at which said first checking value exceeds said first threshold value during the selected observation time window.

According to other embodiments of the present disclosure, the above-mentioned activity of determining said perturbation instant comprises calculating a second checking value indicative of a difference between the selected diagnostic waveform and a reference waveform indicative of an ideal profile of said electrical quantity, during the selected observation time window; comparing said second checking value with a predefined second threshold value; and determining said perturbation instant as an instant, at which said second checking value exceeds said second threshold value, during the selected observation time window.

In a further aspect, the present disclosure provides a diagnostic method for monitoring the operation of a switching apparatus, according to the following claim 9 and the related dependent claims.

### BRIEF DESCRIPTION OF DRAWINGS

Further characteristics and advantages of the present disclosure will become more apparent from the detailed description of some embodiments illustrated only by way of non-limitative example in the accompanying drawings, in which:

FIGS. 1-2 schematically show the switching apparatus of the present disclosure.

FIGS. 3, 3A, 3B, 4, 4A, 4B, 5 schematically show an actuation assembly in the switching apparatus of the present disclosure, according to possible variant embodiments.

FIG. 6 schematically shows a diagnostic method for checking the operating conditions of the switching apparatus, according to the present disclosure.

FIGS. 7-10 schematically show different examples of implementation of the diagnostic method according to the present disclosure.

### DETAILED DESCRIPTION

Referring to the cited figures, the present disclosure is related to a switching apparatus 1 for electrical systems, such as electric grids or switchgears.

In some embodiments, the switching apparatus 1 is a circuit breaker. In principle, however, it may be a switching apparatus of different type, such as a contactor, a disconnector, or the like.

The switching apparatus 1 is particularly adapted for installation in medium voltage electrical systems. In principle, however, it may be employed in electrical systems of different type, such as in low voltage electrical systems.

For the purposes of the present application, the term “low voltage” (LV) relates to operating voltages lower than 2 kV AC and 2.5 kV DC while the term “medium voltage” (MV) relates to higher operating voltages up to tens of kV, e.g., up to 72 kV AC and 100 kV DC.

The switching apparatus 1 comprises one or more switch poles, each of which includes one or more movable contacts 11 and one or more fixed contacts 10.

When the switching apparatus is installed on the field, the electric contacts 10, 11 of each switch pole are electrically connected to corresponding conductors (e.g., a phase conductors or neutral conductors) of an electrical system (not shown).

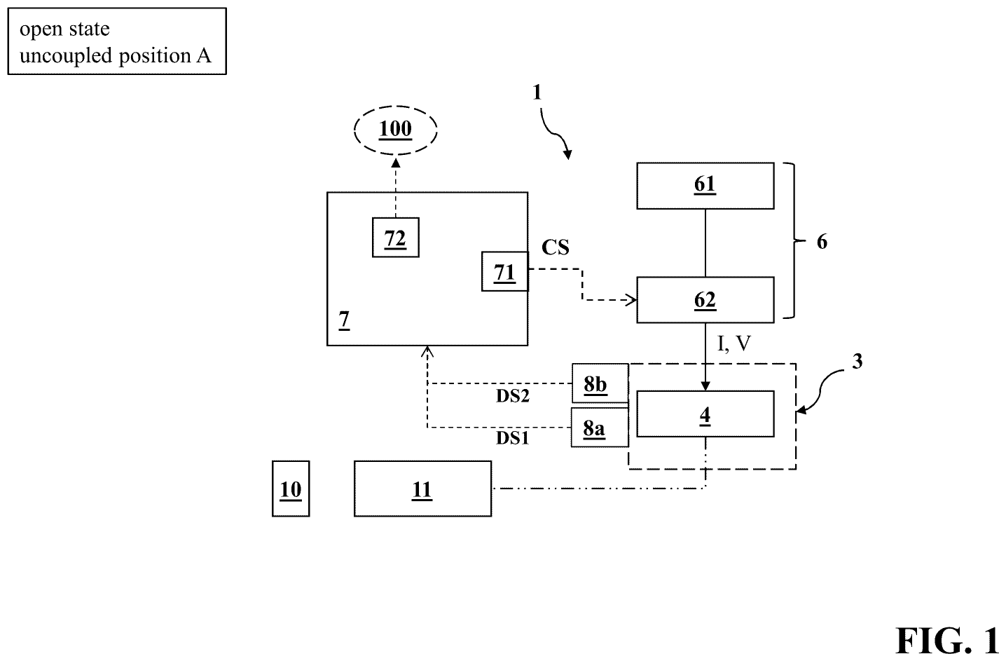

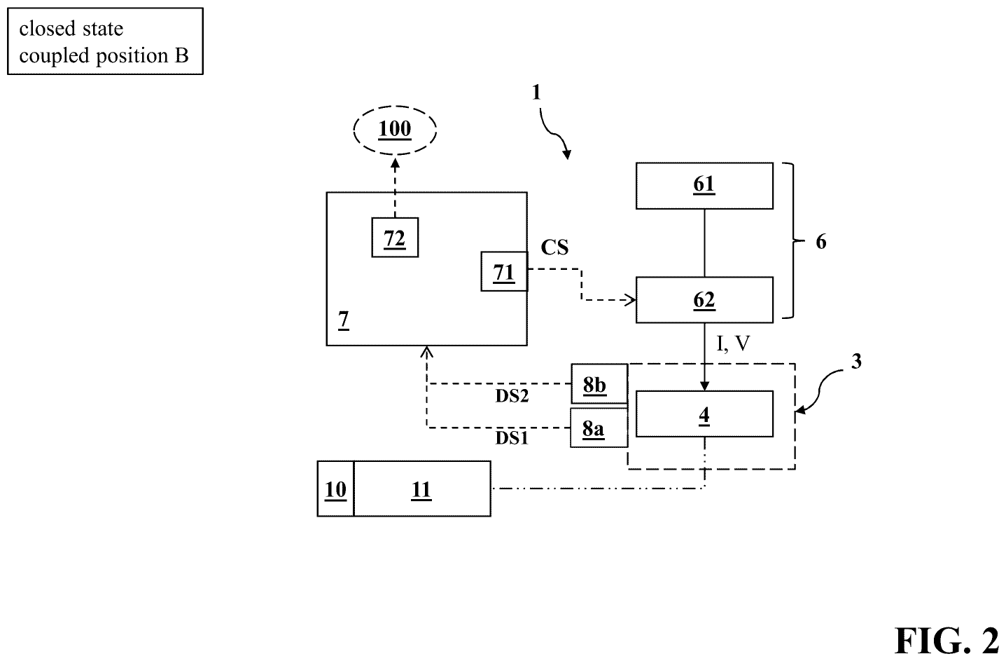

FIGS. 1, 2 schematically show the switching apparatus 1 according to the present disclosure.

The movable contacts 11 are reversibly movable between an uncoupled position A, at which they are decoupled from the corresponding fixed contacts 10, and a coupled position B, at which they are coupled to said fixed contacts.

When the movable contacts 11 are in the uncoupled position A, the switching apparatus is in an open state (FIG. 1). In this situation, electric currents cannot flow through the switch poles.

When the movable contacts 11 are in the coupled position B, the switching apparatus is in a closed state (FIG. 2). In this situation, electric currents can flow through the switch poles.

The switching apparatus 1 is configured to carry out switching maneuvers to electrically connect or disconnect different circuit sections of an electrical system, e.g., for protection purposes or maneuvering purposes.

A switching maneuvers can be a closing maneuvers, during which the movable contacts of the switch poles are moved from the uncoupled position A to the coupled position B, or an opening maneuvers, during which the movable contacts of the switch poles are moved from the coupled position B to the uncoupled position A.

The switching apparatus 1 comprises an actuation assembly 3 to move the movable contacts 11 of the switch poles between the previously mentioned coupled and uncoupled positions A, B in a reversible manner.

According to the present disclosure, the actuation assembly 3 includes an electromagnetic actuator 4.

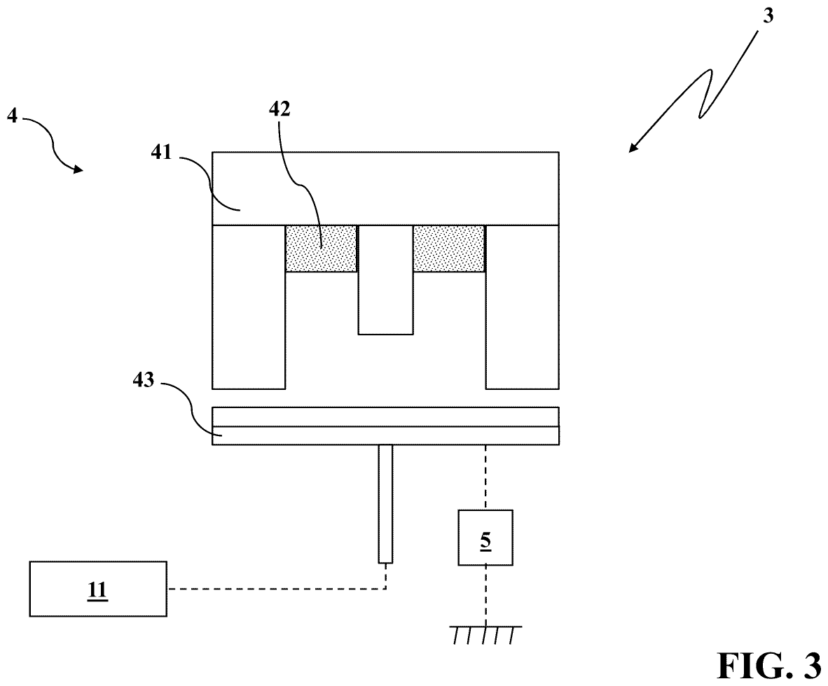

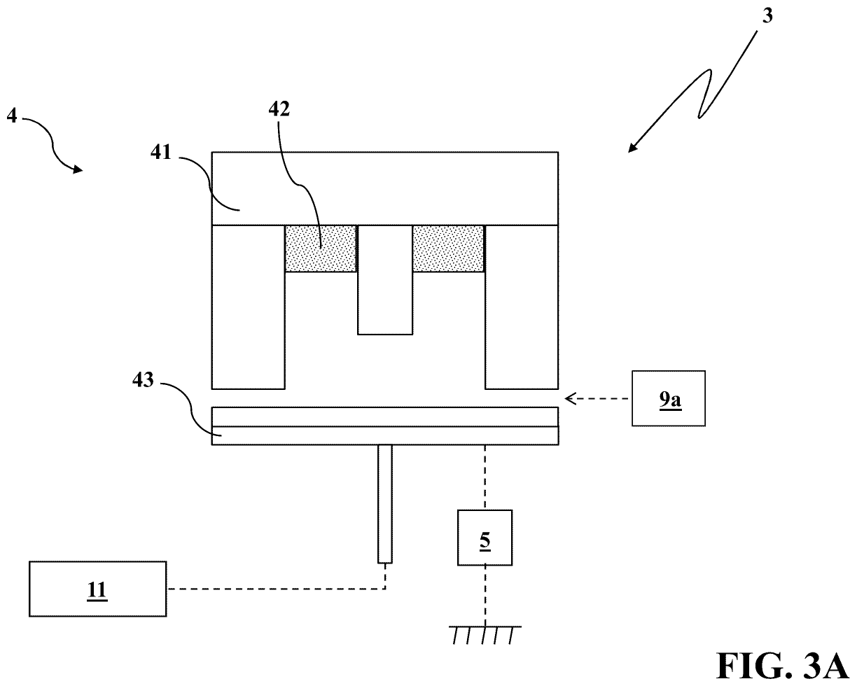

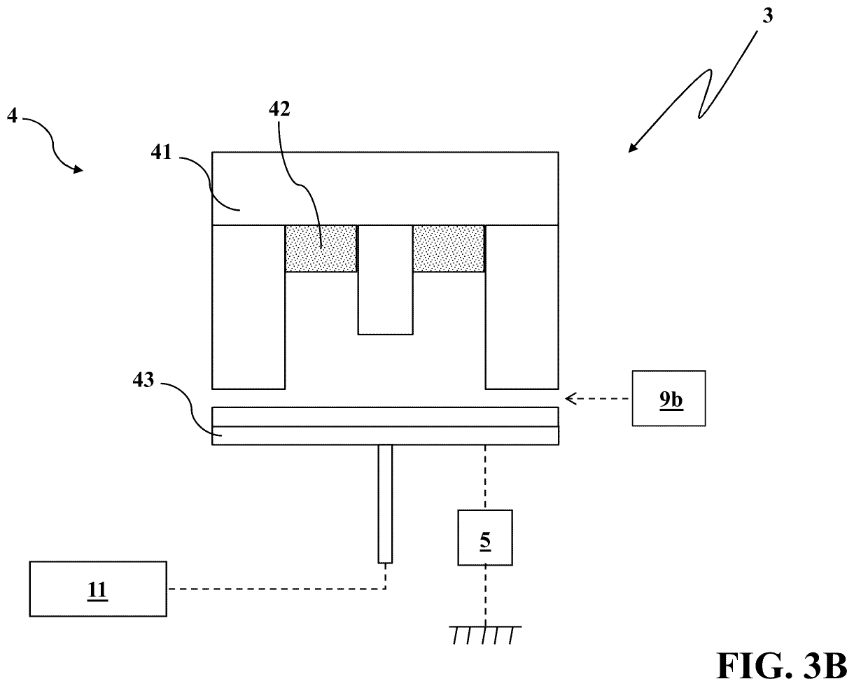

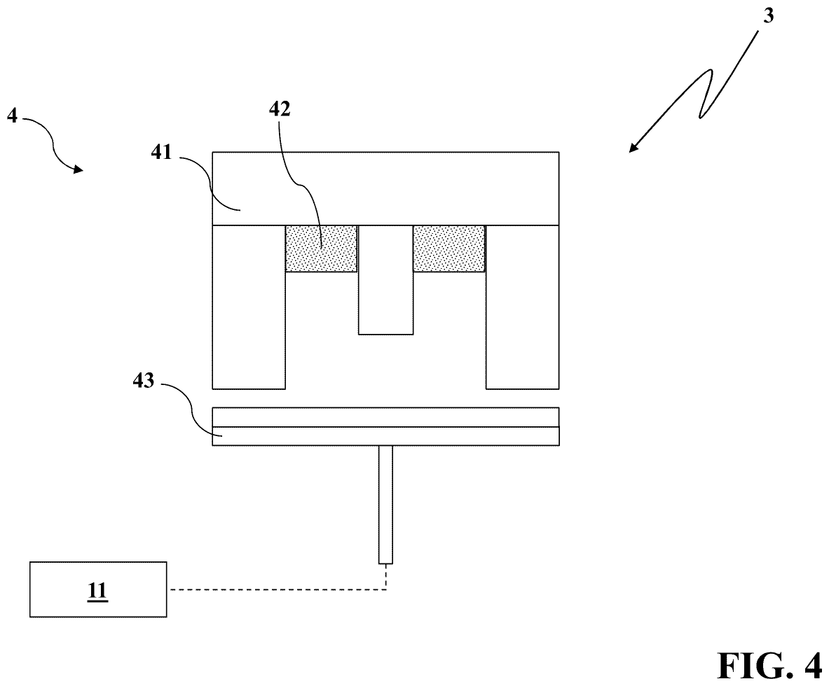

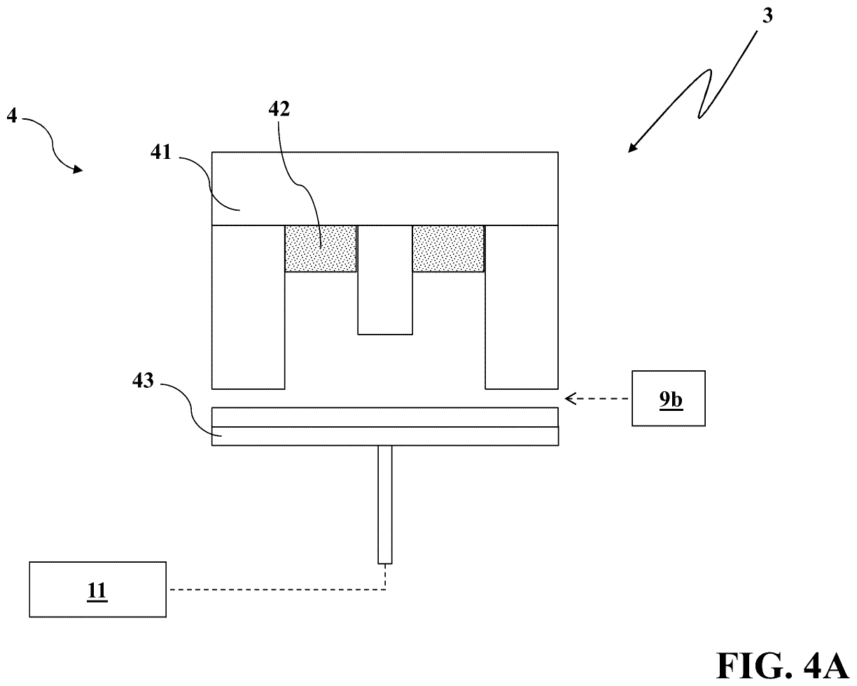

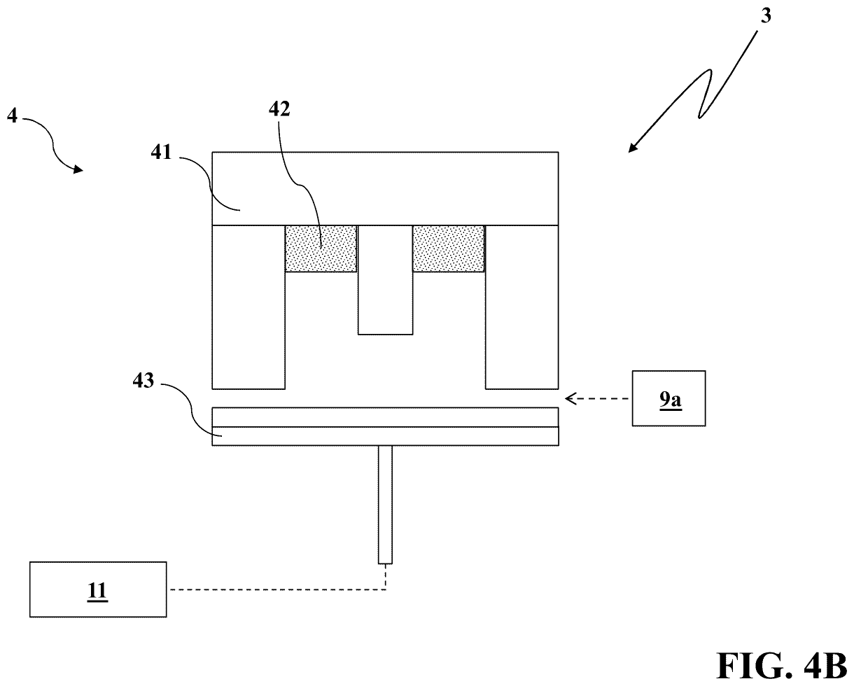

Referring to FIGS. 3, 3A, 3B, 4, 4A and 4B, the electromagnetic actuator 4 in some embodiments includes a magnetic yoke having a fixed yoke member 41 and a movable yoke member 43 mechanically coupled to the movable contacts 11 through a suitable kinematic chain (not shown).

The movable yoke member 43 is reversibly movable between a first position, at which it is coupled to the fixed yoke member 41, and a second position, at which it is decoupled from the fixed yoke member 41.

The first position of the movable yoke member 43 corresponds to the uncoupled position A of the movable contacts 11 (FIG. 1) while the second position of the movable yoke member 43 corresponds to the coupled position B of the movable contacts 11 (FIG. 2).

The electromagnetic actuator 4 further includes an excitation arrangement 42 comprising one or more excitation windings wound around the fixed yoke member 41.

The excitation arrangement 42 can be fed with an excitation current I. This latter, when circulating in the excitation arrangement, generates a magnetic flux flowing along a magnetic circuit formed by the fixed yoke member 41 and the movable yoke member 43. The movable yoke member 43 can thus be actuated by a magnetic force due to the magnetic interaction with the fixed yoke member 41.

According to some embodiments of the present disclosure (FIGS. 3, 3A, 3B), the actuation assembly 3 includes (in addition to the electromagnetic actuator 4) one or more opening springs 5 operatively coupled to the movable contacts 11.

In these embodiments of the present disclosure, the electromagnetic actuator 4 provides actuation forces (of the magnetic type) directed in such a way to move the movable contacts 11 from the uncoupled position A to the coupled position B, during a closing maneuver of the switching apparatus. The opening springs 5 instead provide actuation forces (of the mechanical type) directed in such a way to move the movable contacts 11 from the coupled position B to the uncoupled position A, during an opening maneuver of the switching apparatus.

In some embodiments, the opening springs 5 are mechanically coupled to the movable yoke member 43 of the electromagnetic actuator. They are arranged in such a way to store elastic energy during a closing maneuver of the switching apparatus and release the stored elastic energy during an opening maneuver of the switching apparatus.

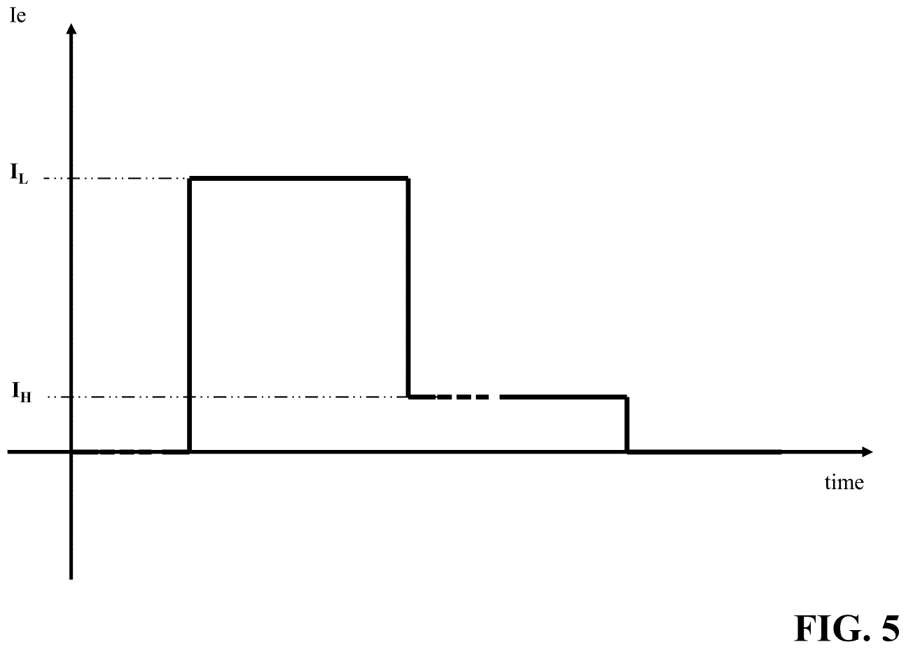

According to some variants (FIGS. 3 and 5), the electromagnetic actuator 4 provides actuation forces (of the magnetic type) directed in such a way to maintain the movable contacts 11 in the coupled position B, when the switching apparatus is in a closed state.

In this case, the excitation arrangement 42 (which can include a single excitation winding) is fed with a first excitation current I_{L} (launch current) during a closing maneuver of the switching apparatus and is fed with a lower second excitation current I_{H} (hold current), when the switching apparatus is in a closed state.

Due to the magnetic interaction with the fixed yoke member 41, the movable yoke member 43 is maintained in the above-mentioned first position, at which it is coupled to the fixed yoke member, until the excitation arrangement 42 is fed with the hold current I_{H}. In fact, the hold current I_{H}, which circulates along the excitation arrangement 42, generates a magnetic flux directed in such a way to provide magnetic forces moving the movable yoke member 43 towards the above-mentioned first position.

To carry out an opening maneuver, the excitation current I_{H} feeding the excitation arrangement 42 is interrupted and the movable yoke member 43 stops interacting magnetically with the fixed yoke member 41. The movable yoke member 43 is free to move away from the fixed yoke member 41 upon the actuation forces provided by the opening springs 5, which can release the stored elastic energy.

According to other variants (FIG. 3A), the actuation assembly comprises a latching mechanism 9a adapted to engage a movable component included in the electromagnetic actuator 4 or operatively coupled to said electromagnetic actuator to maintain the movable contacts 11 in the coupled position B, when the switching apparatus is in a closed state.

In some embodiments, the latching mechanism 9a is adapted to interact mechanically with the movable yoke member 43 of the electromagnetic actuator. To this aim, the latching mechanism 9a can be actuated by a dedicated actuator, such as an actuation coil.

As soon as the switching apparatus has completed a closing maneuver, the latching mechanism 9a engages the movable yoke member 43 and blocks it in the above-mentioned first position, at which it is coupled to the fixed yoke member 41.

To carry out an opening maneuver, the latching mechanism 9a is released. The movable yoke member 43 is free to move away from the fixed yoke member 41 upon the actuation forces provided by the opening springs 5, which can release the stored elastic energy.

As an alternative, the latching mechanism 9a can interact mechanically with a motion transmission member (not shown) mechanically coupling the movable yoke member 43 of the electromagnetic actuator and the movable contacts 11.

According to further variants (FIG. 3B), the actuation assembly comprises one or more permanent magnets 9b operatively coupled to the electromagnetic actuator 4 and adapted to provide actuation forces (of the magnetic type) directed in such a way to maintain the movable contacts 11 in the coupled position B, when the switching apparatus is in a closed state.

The permanent magnets 9b are adapted to generate a magnetic flux flowing along a magnetic circuit formed by the fixed yoke member 41 and the movable yoke member 43 and directed in such a way to provide actuation forces moving the movable yoke member towards the above-mentioned first position, at which it is coupled with the fixed yoke member 41.

When the closing maneuver is completed, the movable contacts 11 are thus maintained in the coupled position even if the excitation arrangement 42 of the electromagnetic actuator is no more fed.

To carry out an opening maneuver, the excitation arrangement 42 (which can include a single excitation winding) is fed with a small excitation current generating a magnetic flux having an opposite direction and a higher intensity compared to the magnetic flux generated by the permanent magnets 9b. The magnetic force generated by the permanent magnets 9b is thus compensated and the movable yoke member 43 is free to move away from the fixed yoke member 41 upon the actuation forces provided by the opening springs 5, which can release the stored elastic energy.

According to some embodiments of the present disclosure (FIGS. 4, 4A, 4B), the electromagnetic actuator 4 provides actuation forces (of the magnetic type) directed in such a way to move the movable contacts 11 from the uncoupled position A to the coupled position B, during a closing maneuver of the switching apparatus, and provides actuation forces of the magnetic type directed in such a way to move the movable contacts 11 from the coupled position B to the uncoupled position A, during an opening maneuver of the switching apparatus.

In this case, the excitation arrangement 42 can advantageously include a closing excitation winding and an opening excitation winding fed with opposite excitation currents during a closing maneuver and an opening maneuver of the switching apparatus.

According to some variants (FIGS. 4 and 5), the electromagnetic actuator 4 provides actuation forces (of the magnetic type) directed in such a way to maintain the movable contacts 11 in the coupled position B, when the switching apparatus is in a closed state.

The excitation arrangement 42 is fed with a first launch current during a closing maneuver of the switching apparatus and is fed with a lower hold current, when the switching apparatus is in a closed state.

The excitation arrangement 42 is fed with a second launch current, which has an opposite direction compared to the above-mentioned first launch current, during an opening maneuver of the switching apparatus and is fed with a lower second hold current, which has an opposite direction compared to the above-mentioned first hold current, when the switching apparatus is in a closed state.

According to other variants (FIG. 4A), the actuation assembly 3 in some embodiments comprises one or more permanent magnets 9b operatively coupled to the electromagnetic actuator 4 and adapted to provide actuation forces (of the magnetic type) directed in such a way to maintain the movable contacts 11 in the coupled position B, when the switching apparatus is in a closed state and in an open state (as explained above).

In some embodiments, actuation assembly 3 comprises also one or more permanent magnets 9b operatively coupled to the electromagnetic actuator 4 and adapted to provide actuation forces (of the magnetic type) directed in such a way to maintain the movable contacts 11 in the uncoupled position A, when the switching apparatus is in an open state.

According to further variants (FIG. 4B), the actuation assembly comprises a latching mechanism 9a adapted to engage a movable component included in the electromagnetic actuator 4 or operatively coupled to said electromagnetic actuator to maintain the movable contacts 11 in the coupled position B and, possibly, in the uncoupled position A, when the switching apparatus is in a closed state and, possibly, in an open state.

In some embodiments, the latching mechanism 9a is adapted to interact mechanically with the movable yoke member 43 of the electromagnetic actuator. As explained above, the latching mechanism 9a can be actuated by a dedicated actuator, such as an actuation coil.

In some embodiments, the switching apparatus 1 further comprises a driving unit 6 electrically connected to the electromagnetic actuator 4 and adapted to feed the electromagnetic actuator with an excitation current I.

Referring again to FIGS. 1-2, in some embodiments the driving unit 6 comprises power supply means 61 to harvest the electric power necessary to operate the electromagnetic actuator 4.

The power supply means 61 may comprise a capacitor bank to store electric energy for operating the electromagnetic actuator 4 and a power supply circuit electrically connected to a power source (for example the electric line on which the switching apparatus is installed) and capable of continuously charging the previously mentioned capacitor bank.

In some embodiments, the driving unit 6 comprises a driving circuit 62 electrically connected to the electromagnetic actuator 4, namely to the excitation arrangement 42, and to the power supply means 61.

The driving circuit 62 is adapted to provide the excitation current to operate the electromagnetic actuator upon receiving suitable control signals CS from an electronic device, for example a control unit of the switching apparatus.

The driving circuit 62 may include one or more suitable switching circuits and other electronic circuits controllable by a suitable control unit.

In some embodiments, the switching apparatus 1 comprises first sensing means 8a adapted to provide first detection signals DS1 indicative of the excitation current I feeding the electromagnetic actuator.

The first sensing means 8a can include, for example, one or more current sensors (e.g., current transformers, Hall sensors, shunt circuits, and the like) operatively coupled to the excitation arrangement 42 of the electromagnetic actuator.

In some embodiments, the switching apparatus 1 comprises second sensing means 8b adapted to provide second detection signals DS2 indicative of a voltage V feeding the electromagnetic actuator 4. The second sensing means 8b can include, for example, one or more voltage sensors (e.g., capacitive sensors, shunt circuits, and the like) operatively coupled to the excitation arrangement 42 of the electromagnetic actuator.

In general terms, the above-mentioned actuation assembly 3, driving unit 6 and sensing means 8a, 8b may be arranged to solutions of known type. Therefore, these components of the switching apparatus will be described hereinafter only in relation to the sole aspects of interest of the present disclosure, for the sake of brevity.

The switching apparatus 1 comprises a control unit 7 for controlling the operation of the switching apparatus (FIGS. 1-2).

In some embodiments, the control unit 7 comprises suitable digital processing devices (e.g., one or more microprocessors) adapted to execute software instructions to generate control/data signals to manage the operating life of the switching apparatus 1. In principle, however, the control unit 7 may include electronic circuits of the analogic type suitably configured to carry out the requested functionalities.

The control unit 7 is operatively coupled to the driving unit 6 and is configured to control the latter by providing suitable control signals CS, for example to the driving circuit 62. Conveniently, the control unit 7 is operatively coupled also to the sensing means 8a, 8b to receive the above-mentioned detection data DS1, DS2 from the latter.

In some embodiments, the control unit 7 comprises a regulator block 71 configured to control the driving unit 6 based on the detection signals DS1, DS2 provided by the sensor means 8a, 8b.

The regulator block 71 may include, for example, a PID regulator.

In some embodiments, the above-mentioned switching circuits of the driving unit 6 and the sensor means 8a, 8b implement a control loop configured to carry out a PWM regulation of the excitation current I feeding the electromagnetic actuator. The electromagnetic actuator 4 can thus be fed as described above during the operation of the switching apparatus.

In some embodiments, the regulator block 71 is digitally implemented. In this case, a microcontroller of the control unit 7 can execute suitable software instructions for implementing the functionalities requested to the regulator block.

The control unit 7 can be a controller installed on-board the switching apparatus. As an alternatively, it may be a stand-alone device installed at local level, for example a digital relay.

An important feature of the present disclosure consists in that the control unit 7 is configured to execute a diagnostic method 100 to monitor the operation of said switching apparatus during a switching maneuver.

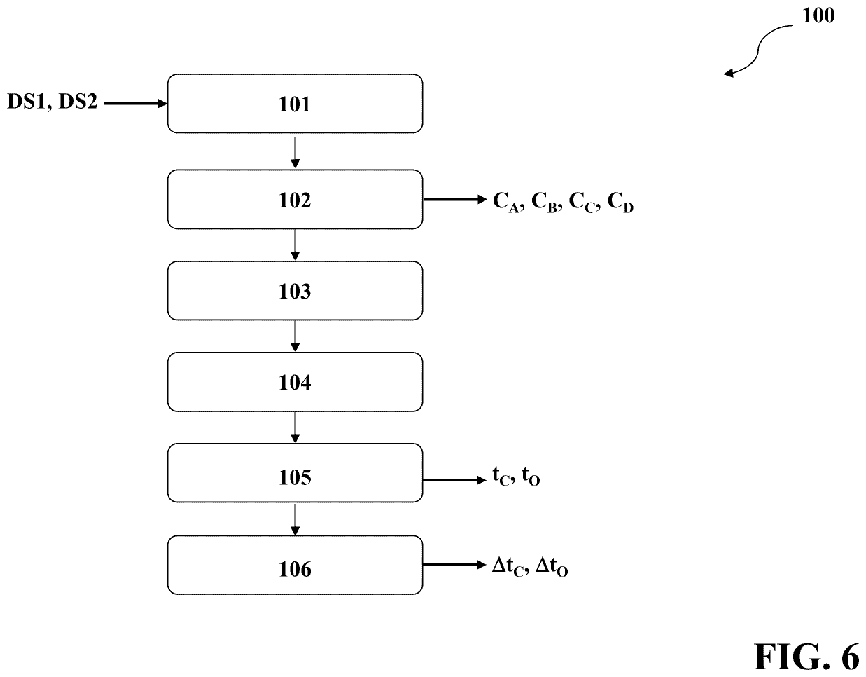

The steps of the diagnostic method 100 are now described in detail (FIG. 6).

The diagnostic method 100 comprises a step 101 of acquiring detection signals indicative of one or more electrical quantities of the switching apparatus, during a switching maneuver of this latter.

In some embodiments, the above-mentioned one or more electrical quantities include at least one between the following quantities: the voltage V feeding the electromagnetic actuator 4; and the excitation current I feeding the electromagnetic actuator 4.

In some embodiments, the diagnostic signals acquired in this step of the diagnostic method 100 are the diagnostic signals DS1, DS2 provided by the first and second sensing means 8a, 8b.

It is evidenced how these sensing means are not exclusively dedicated to the execution of the diagnostic method 100. As mentioned above, these components are basically arranged for implementing a control loop of the operation of the electromagnetic actuator. The diagnostic method 100 of the present disclosure, however, exploits the detection information provided by these components for monitoring purposes.

The diagnostic method 100 comprises a step 102 of calculating, for each monitored electrical quantity V, I, a diagnostic waveform C_{A}, C_{B}, C_{C}, C_{D} indicative of an actual behavior of said electrical quantity, during a switching maneuver of said switching apparatus. The one or more diagnostic waveforms C_{A}, C_{B}, C_{C}, C_{D} are conveniently reconstructed based on the acquired detection signals DS1, DS2.

The diagnostic method 100 comprises a step 103 of selecting a timing parameter to be calculated in relation to a switching maneuver of the switching apparatus.

As an example, a timing parameter can be the separation time Δt_{O} of the electric contacts of the switch poles during an opening maneuver. Anomalies in this timing parameter may be indicative of potential problems in the actuation chain of the movable contacts 11, namely in the electromagnetic actuator 4 or in the kinematic chain coupling the movable contacts 11 with the electromagnetic actuator.

As a further example, another timing parameter can be the closing time Δt_{C} of the electric contacts of the switch poles during a closing maneuver. Anomalies in this timing parameters may be indicative of a relevant erosion condition of the electric contacts.

Additional timing parameters may be selected according to the needs, for example with the aim of reconstruct the travel waveforms of the movable contacts 11 during a switching maneuver of the switching apparatus.

The diagnostic method 100 comprises a step 104 of selecting a diagnostic waveform C_{A}, C_{B}, C_{C}, C_{D} and an observation time window T_{A}, T_{B}, T_{C}, T_{D} to check the selected timing parameter.

At this stage of the diagnostic method 100, the most suitable diagnostic waveform and observation time window to check the selected timing parameter is chosen.

For example, if the selected timing parameter is the closing time Δt_{C} of the electric contacts during a closing maneuver, a diagnostic waveform indicative of the actual behavior of the excitation current I feeding the electromagnetic actuator 4 can be selected. A selected time window can be a time interval, during which the selected diagnostic waveform shows a stationary profile. As an alternative, a selected time window can start from an instant at which the selected diagnostic waveform exceeds a predefined value. Obviously, as it will be more apparent from the examples described below, different diagnostic waveforms and observation time windows can be selected to check a same selected time parameter.

The diagnostic method 100 comprises a step 105 of determining a perturbation instant t_{C}, t_{O} in the selected diagnostic waveform C_{A}, C_{B}, C_{C}, C_{D} during the selected observation time window T_{A}, T_{B}, T_{C}, T_{D}.

For the sake of clarity, it is specified that a “perturbation instant” should be intended as an instant, at which the selected diagnostic waveform shows a sudden change of its profile.

The identification of an perturbation instant t_{C}, t_{O} in a selected diagnostic waveform C_{A}, C_{B}, C_{C}, C_{D} (i.e., in the monitored electric quantities) allows understanding when the electrical contacts 10, 11 of the switch poles actually change their operating conditions during a switching operation of the switching apparatus, thereby passing from a coupled condition to a separated condition, or vice-versa. The inventors have, in fact, observed that the presence of a perturbation instant t_{C}, t_{O} in a selected diagnostic waveform C_{A}, C_{B}, C_{C}, C_{D} is strictly correlated to a change of the operating conditions of the actuation assembly 4 operatively coupled to the movable contact 11, thus being linked to the actual the travel law of the movable contact.

The diagnostic method 100 then comprises a step 106 of calculating the selected timing parameter Δt_{C}, Δt_{O} based on the identified perturbation instant t_{C}, t_{O}. As an example, the selected timing parameter perturbation instant Δt_{C}, Δt_{O} can be calculated by measuring the time elapsing between an initial instant t₀ (which is obviously known) of the monitored switching maneuver and the determined perturbation instant t_{C}, t_{O}.

According to certain embodiments of the present disclosure, the identification step of a perturbation instant t_{C} in a selected diagnostic waveform C_{A}, C_{B} is based on the calculation of the derivative over time of the selected diagnostic waveform.

In some embodiments, the step 105 of determining the perturbation instant t_{C} includes calculating a first checking value ck_{A}, ck_{B} indicative of the derivative over time of the selected diagnostic waveform C_{A}, C_{B} during the selected observation time window T_{A}, T_{B}; comparing the calculated first checking value ck_{A}, ck_{B} with a predefined first threshold value TH_{A}, TH_{B}; and determining the perturbation instant t_{C} as the instant at which the calculated first checking value ck_{A}, ck_{B} exceeds the first threshold value TH_{A}, TH_{B} during the selected observation time window.

According to other embodiments of the present disclosure, the identification step of a perturbation instant t_{C}, t_{O} in a selected diagnostic waveform C_{C}, C_{D} is based on the calculation of a difference value between said diagnostic waveform and a reference waveform R_{C}, R_{D} indicative of an ideal profile for the monitored electrical quantity.

In some embodiments, the step 105 of determining the perturbation instant t_{C}, t_{O} includes calculating a second checking value ck_{C}, ck_{D} indicative of a difference between the selected diagnostic waveform C_{C}, C_{D} and a reference waveform R_{C}, R_{D} indicative of an ideal profile of the electrical quantity V, I during the selected observation time window T_{C}, T_{D}; comparing the calculated second checking value ck_{C}, ck_{D} with a predefined second threshold value TH_{C}, TH_{D}; and determining the perturbation instant t_{C}, t_{O} as the instant at which the calculated second checking value ck_{C}, ck_{D} exceeds the second threshold value TH_{C}, TH_{D} during the selected observation time window.

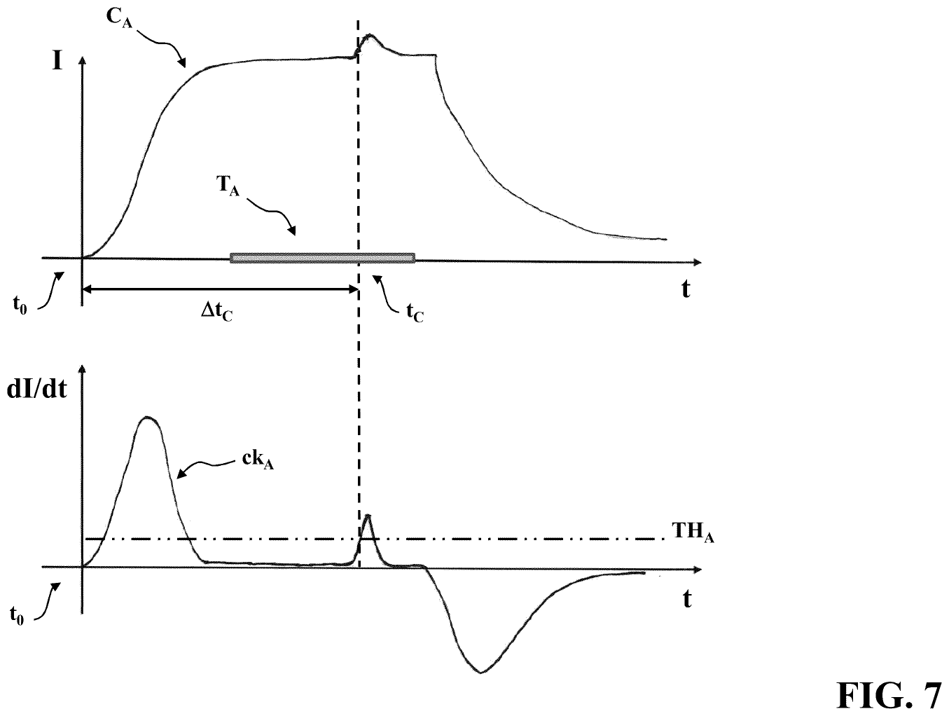

FIG. 7 shows an example of practical implementation of the diagnostic method 100 according to the present disclosure.

In this case, the selected timing parameter to be calculated is the closing time Δt_{C} of the electric contacts 10, 11 during the closing maneuver of a switching apparatus equipped with an electromagnetic actuator according to the embodiment of FIGS. 3-4.

A diagnostic waveform C_{A} indicative of the actual behavior of a current I feeding the electromagnetic actuator 4 during a closing maneuver of the switching apparatus is selected. The selected current waveform C_{A} has been calculated based on the acquired first detection signals DS1 provided by the first sensing means 8A.

An observation time window T_{A} is selected, during which the selected current waveform C_{A} shows a stationary profile.

A perturbation instant t_{C} in the selected current waveform C_{A} during the selected observation time window T_{A} is determined. To this aim, it is calculated a first checking value ck_{A} indicative of the derivative over time of the selected current waveform C_{A} during the selected observation time window T_{A}. The calculated first checking value ck_{A} is then compared with a predefined first threshold value TH_{A}.

The perturbation instant t_{C} (closing instant of the electric contacts) is identified as the instant in which the first checking value ck_{A} exceeds the predefined first threshold value TH_{A} during the selected observation time window.

The closing time Δt_{C} of the electric contacts 10, 11 during the closing maneuver is calculated based on the following relation:

$$Δ {t}_{C} = {t}_{C} - {t}_{0}$$

where t_{C} is the determined perturbation instant and t₀ is the initial instant of the closing maneuver.

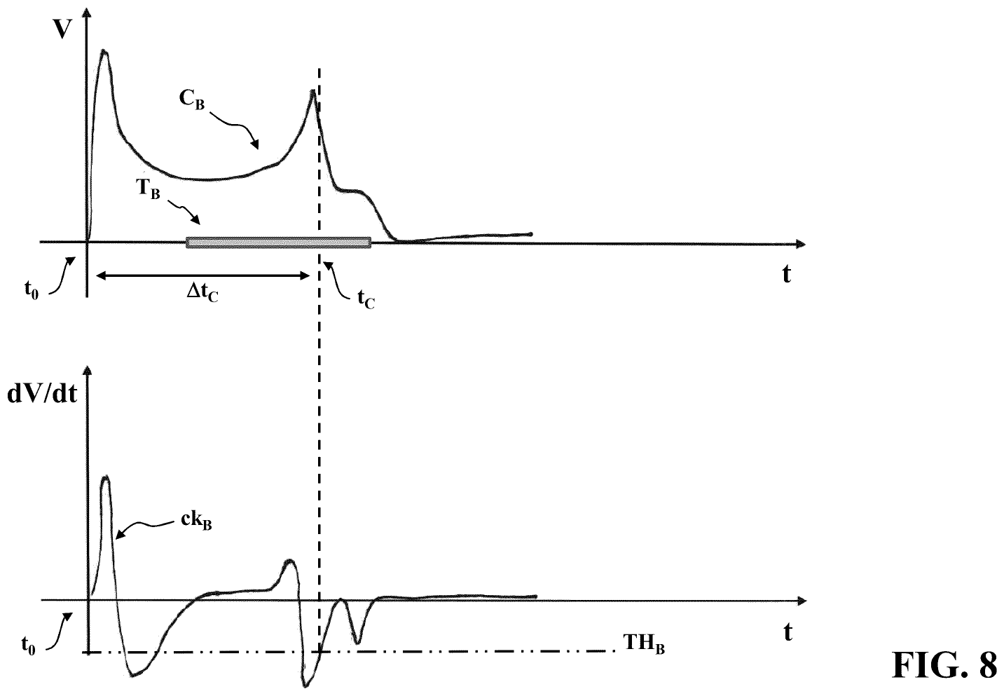

FIG. 8 shows a further example of practical implementation of the diagnostic method 100 according to the present disclosure.

Also in this case, the selected timing parameter to be calculated is the closing time Δt_{C} of the electric contacts 10, 11 during the closing maneuver of a switching apparatus equipped with an electromagnetic actuator according to the embodiment of FIG. 3.

A diagnostic waveform C_{B} indicative of the actual behavior of a voltage V feeding the electromagnetic actuator 4 of the switching apparatus is selected. The selected current waveform C_{B} has been calculated based on the acquired second detection signals DS2 provided by the second sensing means 8B. An observation time window T_{B} is selected, during which the selected voltage waveform C_{B} shows a stationary profile.

A perturbation instant t_{C} in the selected voltage waveform C_{B} during the selected observation time window T_{B} is determined. To this aim, it is calculated a first checking value ck_{B} indicative of the derivative over time of the selected voltage waveform C_{B} during the selected observation time window T_{B}. The calculated second checking value ck_{B} is then compared with a predefined first threshold value TH_{B}.

The perturbation instant t_{C} (closing instant of the electric contacts) is identified as the instant in which the first checking value ck_{B} exceeds (in module) the predefined first threshold value TH_{B} during the selected observation time window.

The closing time Δt_{C} of the electric contacts 10, 11 during the closing maneuver is calculated based on the following relation:

$$Δ {t}_{C} = {t}_{C} - {t}_{0}$$

where t_{C} is the determined perturbation instant and t₀ is the initial instant of the closing maneuver.

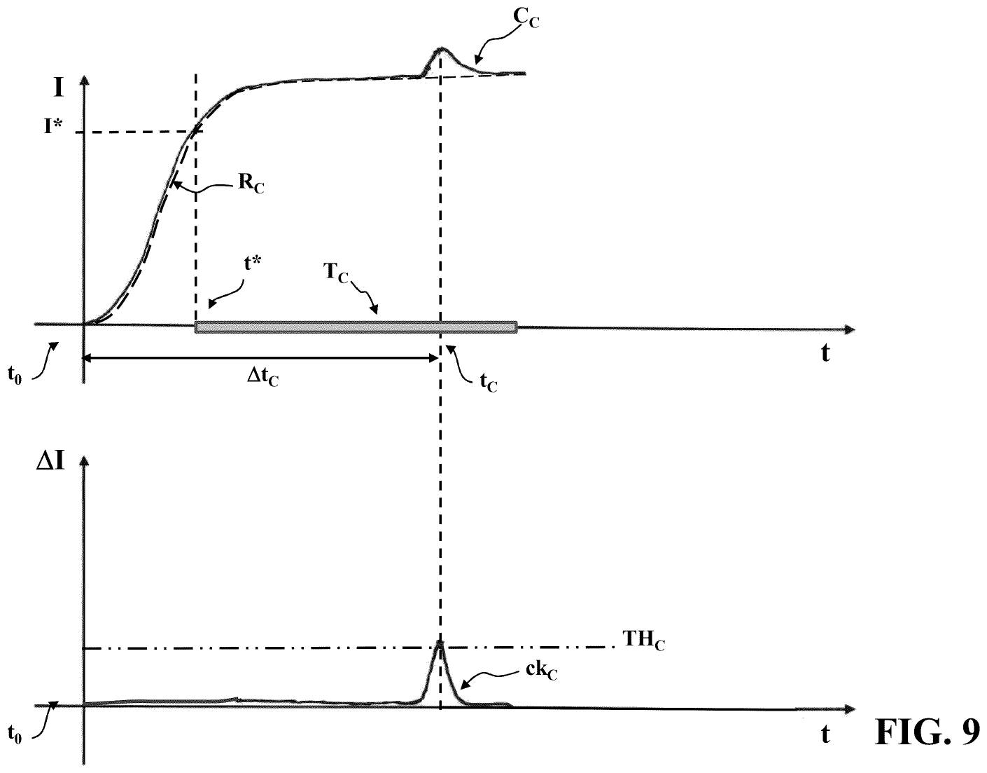

FIG. 9 shows a further example of practical implementation of the diagnostic method 100 according to the present disclosure.

In this case, the selected timing parameter to be calculated is the closing time Δt_{C} of the electric contacts 10, 11 during the closing maneuver of a switching apparatus equipped with an electromagnetic actuator according to the embodiment of FIG. 4.

A diagnostic waveform C_{C} indicative of the actual behavior of a current I feeding the electromagnetic actuator 4 during a closing maneuver of the switching apparatus is selected. The selected current waveform C_{C} has been calculated based on the acquired first detection signals DS1 provided by the first sensing means 8A.

An observation time window T_{C} is selected. The observation time window T_{C} starts from an instant t* at which the selected current waveform C_{D} exceeds a predefined value I*.

A perturbation instant t_{C} in the selected current waveform C_{C} during the selected observation time window T_{C} is determined. To this aim, it is calculated a second checking value ck_{C} indicative of a difference between the selected current waveform C_{C} and a reference waveform R_{C} indicative of an ideal profile of the current circulating the electromagnetic actuator during a closing maneuver. The calculated second checking value ck_{C} is then compared with a predefined second threshold value TH_{C}.

The perturbation instant t_{C} (closing instant of the electric contacts) is identified as the instant in which the second checking value ck_{C} exceeds the predefined first threshold value TH_{C} during the selected observation time window.

The closing time Δt_{C} of the electric contacts 10, 11 during the closing maneuver is calculated based on the following relation:

$$Δ {t}_{C} = {t}_{C} - {t}_{0}$$

where t_{C} is the determined perturbation instant and t₀ is the initial instant of the closing maneuver.

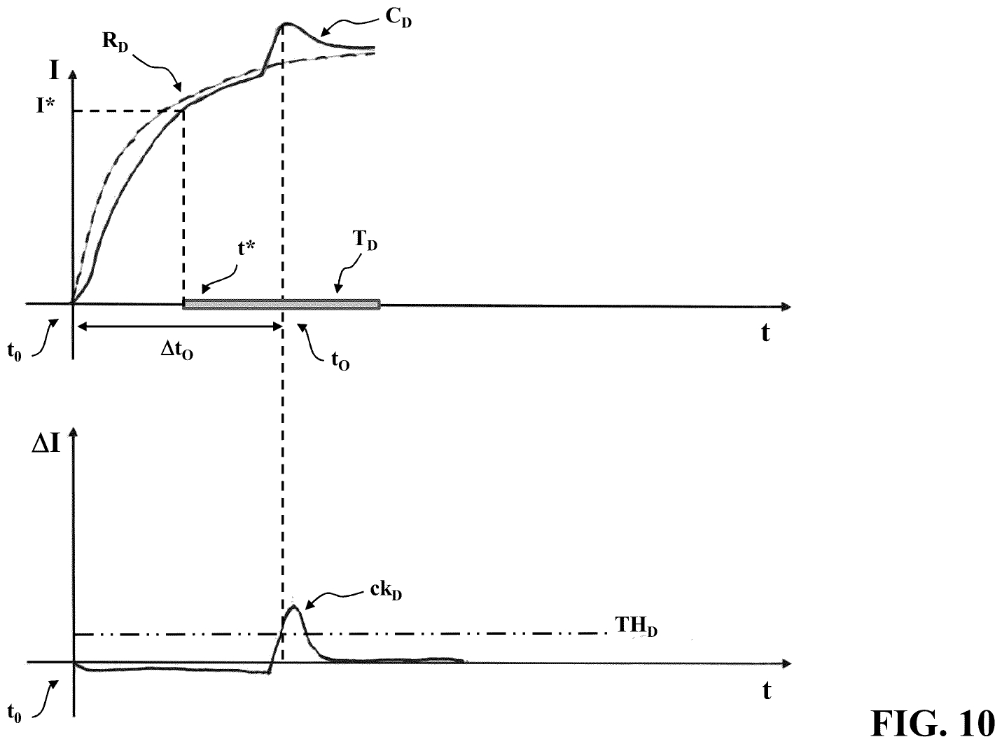

FIG. 10 shows a further example of practical implementation of the diagnostic method 100 according to the present disclosure.

In this case, the selected timing parameter to be calculated is the opening time Δt_{O} of the electric contacts 10, 11 during the opening maneuver of a switching apparatus equipped with an electromagnetic actuator according to the embodiment of FIG. 4.

A diagnostic waveform C_{D} indicative of the actual behavior of a current I feeding the electromagnetic actuator 4 during an opening maneuver of the switching apparatus is selected. The selected current waveform C_{D} has been calculated based on the acquired first detection signals DS1 provided by the first sensing means 8A.

An observation time window T_{D} is selected. The observation time window T_{D} starts from an instant t* at which the selected current waveform C_{D} exceeds a predefined value I*.

A perturbation instant to in the selected current waveform C_{D} during the selected observation time window T_{D} is determined. To this aim, it is calculated a second checking value ck_{D} indicative of a difference between the selected current waveform C_{D} and a reference waveform R_{D} indicative of an ideal profile of the current circulating the electromagnetic actuator during an opening maneuver. The calculated second checking value ck_{D} is then compared with a predefined second threshold value TH_{D}.

The perturbation instant t_{O} (opening instant of the electric contacts) is identified as the instant in which the second checking value ck_{D} exceeds the predefined second threshold value TH_{D} during the selected observation time window.

The opening time Δt_{O} of the electric contacts 10, 11 during the opening maneuver is calculated based on the following relation:

$$Δ {t}_{O} = {t}_{O} - {t}_{0}$$

where t_{C} is the determined perturbation instant and t₀ is the initial instant of the opening maneuver.

In some embodiments, the control unit 7 comprises a monitoring block 72 configured to execute the diagnostic method 100. In some embodiments, the monitoring block 71 is digitally implemented. In this case, a microcontroller of the control unit 7 can execute suitable software instructions for carrying out the functionalities requested to the monitoring block.

As it is apparent from the above, in another aspect, the present disclosure relates to a diagnostic method 100 for monitoring the operating conditions of a switching apparatus 1, during a switching maneuver of a switching apparatus (FIG. 6).

The diagnostic method 100 comprises at 101 acquiring detection signals DS1, DS2 indicative of one or more electrical quantities V, I related to the operation of the switching apparatus, during a switching maneuver of said switching apparatus; at 102 calculating, based on said detection signals, for each electrical quantity V, I, a diagnostic waveform C_{A}, C_{B}, C_{C}, C_{D} indicative of an actual behavior of said electrical quantity, during a switching maneuver of said switching apparatus; at 103 selecting a timing parameter Δt_{C}, Δt_{O} to be calculated in relation to a switching maneuver of said switching apparatus; at 104 selecting a diagnostic waveform C_{A}, C_{B}, C_{C}, C_{D} and an observation time window T_{A}, T_{B}, T_{C}, T_{D} to calculate the selected timing parameter Δt_{C}, Δt_{O}; at 105 determining a perturbation instant t_{C}, t_{O} in the selected diagnostic waveform C_{A}, C_{B}, C_{C}, C_{D} during the selected observation time window T_{A}, T_{B}, T_{C}, T_{D}; and at 106 calculating the selected timing parameter Δt_{C}, Δt based on the determined perturbation instant t_{C}, t_{O}.

According to certain embodiments of the present disclosure, at 105 determining the perturbation instant t_{C} comprises calculating a first checking value ck_{A}, ck_{B} indicative of the derivative over time of the selected diagnostic waveform C_{A}, C_{B} during the selected observation time window T_{A}, T_{B}; comparing the calculated first checking value ck_{A}, ck_{B} within a predefined first threshold value TH_{A}, TH_{B}; and determining said perturbation instant t_{C} as an instant, at which the calculated first checking value ck_{A}, ck_{B} exceeds the first threshold value TH_{A}, TH_{B} during the selected observation time window T_{A}, T_{B}.

According to other embodiments of the present disclosure, at 105 determining the perturbation instant t_{C} comprises calculating a second checking value ck_{C}, ck_{D} indicative of a difference between the selected diagnostic waveform C_{C}, C_{D} and a reference waveform RC, R_{D} indicative of an ideal profile of the monitored electrical quantity V, I during the selected observation time window T_{C}, T_{D}; comparing the calculated second checking value ck_{C}, ck_{D} with a predefined second threshold value TH_{C}, TH_{D}; and determining said perturbation instant t_{C}, t_{O} as an instant, at which the calculated second checking value ck_{C}, ck_{D} exceeds the second threshold value TH_{C}, TH_{D} during the selected observation time window T_{C}, T_{D}.

The switching apparatus and the control method, according to the present disclosure, provides remarkable advantages with respect to the solutions of the state of the art.

In the switching apparatus of the present disclosure, detection information, which is normally available for controlling the operation of the electromagnetic actuator, is processed through simple mathematical operations to reconstruct empirically diagnostic information (the calculated timing parameters) about the actual performances of the switching apparatus, particularly during the switching operations.

Different from currently available solutions of the state of the art, for example the solution described in EP3460822A1, such diagnostic information is empirically reconstructed without the use of dedicated mathematical models describing the operation of the electromagnetic actuator. Therefore, such diagnostic information can be collected easily without the need for dedicated sensing arrangements and performant data-processing resources.

The presence of anomalies in the electric contacts, in the electromagnetic actuator and in the kinematic chain coupling the electromagnetic contacts with the electromagnetic actuator can thus be determined based on the collected diagnostic information.

This allows suitably intervening or planning maintenance operations to prevent malfunctioning or faults of the switching apparatus.

The switching apparatus of the present disclosure is of relatively easy manufacturability at industrial levels, at competitive costs with respect to the solutions of the state of the art.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

1. A switching apparatus for electrical systems, wherein the switching apparatus comprises:
one or more switch poles;
for each switch pole, one or more fixed contacts and one or more movable contacts, wherein the movable contacts are reversibly movable between an uncoupled position, at which the movable contacts are decoupled from the fixed contacts, and a coupled position, at which the movable contacts are coupled with the fixed contacts;
an actuation assembly operatively coupled to the movable contacts, wherein the actuation assembly includes an electromagnetic actuator, wherein:
the switching apparatus is operatively coupled to a control unit,
the control unit is configured to carry out a diagnostic to monitor the operation of the switching apparatus during a switching maneuver,
the control unit is configured to:
acquire detection signals indicative of one or more electrical quantities related to the operation of the switching apparatus, during a switching maneuver of the switching apparatus;
based on the detection signals, calculate, for each electrical quantity, a diagnostic waveform indicative of an actual behavior of the electrical quantity, during a switching maneuver of the switching apparatus;
select a timing parameter to be calculated in relation to a switching maneuver of the switching apparatus;
select a diagnostic waveform and an observation time window to calculate the selected timing parameter;
determine a perturbation instant in the selected diagnostic waveform during the selected observation time window; and
calculate the selected timing parameter based on the determined perturbation instant.

2. The switching apparatus, according to claim 1, wherein to determine the perturbation instant, the control unit is configured to:
calculate a first checking value indicative of the derivative over time of the selected diagnostic waveform during the selected observation time window;
compare the first checking value within a predefined first threshold value; and
determine the perturbation instant as an instant, at which the first checking value exceeds the first threshold value during the selected observation time window.

3. The switching apparatus, according to claim 1, wherein to identify the perturbation instance, the control unit is configured to:
calculate a second checking value indicative of a difference between the selected diagnostic waveform and a reference waveform indicative of an ideal profile of the electrical quantity during the selected observation time window;
compare the second checking value with a predefined second threshold value; and
determine the perturbation instant as an instant, at which the second checking value exceeds the second threshold value during the selected observation time window.

4. The switching apparatus, according to claim 1, wherein the one or more electrical quantities include at least one of:
a voltage feeding the electromagnetic actuator; and
an excitation current feeding the electromagnetic actuator.

5. The switching apparatus, according to claim 1, wherein the actuation assembly includes one or more opening springs operatively coupled to the movable contacts, wherein the electromagnetic actuator is configured to provide actuation forces directed to move the movable contacts from the uncoupled position to the coupled position, during a closing maneuver of the switching apparatus, wherein the opening springs are configured to provide actuation forces directed to move the movable contacts from the coupled position to the uncoupled position, during an opening maneuver of the switching apparatus.

6. The switching apparatus, according to claim 1, wherein the electromagnetic actuator is configured to provide actuation forces directed to move the movable contacts from the uncoupled position to the coupled position, during a closing maneuver of the switching apparatus, and to move the movable contacts from the coupled position to the uncoupled position, during an opening maneuver of the switching apparatus.

7. The switching apparatus, according to claim 1, wherein the switching apparatus comprises a driving unit electrically connected to the electromagnetic actuator and configured to feed the electromagnetic actuator with an excitation current to operate the electromagnetic actuator.

8. The switching apparatus according to claim 1, wherein the switching apparatus is a medium voltage switching apparatus.

9. A diagnostic method for monitoring the operation of a switching apparatus (1) during a switching maneuver, wherein the switching apparatus comprises:
one or more switch poles;
for each switch pole, one or more fixed contacts and one or more movable contacts, wherein the movable contacts are reversibly movable between an uncoupled position, at which the movable contacts are decoupled from the fixed contacts, and a coupled position, at which the movable contacts are coupled with the fixed contacts;
an actuation assembly operatively coupled to the movable contacts, wherein the actuation assembly includes an electromagnetic actuator;
wherein the diagnostic method comprises:
acquiring detection signals indicative of one or more electrical quantities related to the operation of the switching apparatus, during a switching maneuver of the switching apparatus;
based on the detection signals, calculating, for each electrical quantity, a diagnostic waveform indicative of an actual behavior of the electrical quantity, during a switching maneuver of the switching apparatus;
selecting a timing parameter to be calculated in relation to a switching maneuver of the switching apparatus;
selecting a diagnostic waveform and an observation time window to calculate the selected timing parameter;
determining a perturbation instant in the selected diagnostic waveform during the selected observation time window; and
calculating the selected timing parameter based on the determined perturbation instant.

10. The diagnostic method, according to claim 9, wherein determining the perturbation instant comprises:
calculating a first checking value indicative of the derivative over time of the selected diagnostic waveform during the selected observation time window;
comparing the first checking value within a predefined first threshold value; and
determining the perturbation instant as an instant, at which the first checking value exceeds the first threshold value during the selected observation time window.

11. The diagnostic method, according to claim 9, wherein the perturbation instant is identified by:
calculating a second checking value indicative of a difference between the selected diagnostic waveform and a reference waveform indicative of an ideal profile of the electrical quantity during the selected observation time window;
comparing the second checking value with a predefined second threshold value; and
determining the perturbation instant as an instant, at which the second checking value exceeds the second threshold value during the selected observation time window.

12. The diagnostic method, according to claim 9, wherein the one or more electrical quantities include at least one between:
a voltage feeding the electromagnetic actuator; and
an excitation current feeding the electromagnetic actuator.

13. The diagnostic method, according to claim 10, wherein the perturbation instant is identified by:
calculating a second checking value indicative of a difference between the selected diagnostic waveform and a reference waveform indicative of an ideal profile of the electrical quantity during the selected observation time window;
comparing the second checking value with a predefined second threshold value; and
determining the perturbation instant as an instant, at which the second checking value exceeds the second threshold value during the selected observation time window.

14. The diagnostic method, according to claim 10, wherein the one or more electrical quantities include at least one of:
a voltage feeding the electromagnetic actuator; and
an excitation current feeding the electromagnetic actuator.

15. The diagnostic method, according to claim 11, wherein the one or more electrical quantities include at least one of:
a voltage feeding the electromagnetic actuator; and
an excitation current feeding the electromagnetic actuator.

16. The switching apparatus, according to claim 2, wherein to identify the perturbation instance, the control unit is configured to:
calculate a second checking value indicative of a difference between the selected diagnostic waveform and a reference waveform indicative of an ideal profile of the electrical quantity during the selected observation time window;
compare the second checking value with a predefined second threshold value; and
determine the perturbation instant as an instant, at which the second checking value exceeds the second threshold value during the selected observation time window.

17. The switching apparatus, according to claim 2, wherein the one or more electrical quantities include at least one of:
a voltage feeding the electromagnetic actuator; and
an excitation current feeding the electromagnetic actuator.

18. The switching apparatus, according to claim 3, wherein the one or more electrical quantities include at least one of:
a voltage feeding the electromagnetic actuator; and
an excitation current feeding the electromagnetic actuator.

19. The switching apparatus, according to claim 2, wherein the actuation assembly includes one or more opening springs operatively coupled to the movable contacts, wherein the electromagnetic actuator is configured to provide actuation forces directed to move the movable contacts from the uncoupled position to the coupled position, during a closing maneuver of the switching apparatus, wherein the opening springs are configured to provide actuation forces directed to move the movable contacts from the coupled position to the uncoupled position, during an opening maneuver of the switching apparatus.

20. The switching apparatus, according to claim 3, wherein the actuation assembly includes one or more opening springs operatively coupled to the movable contacts, wherein the electromagnetic actuator is configured to provide actuation forces directed to move the movable contacts from the uncoupled position to the coupled position, during a closing maneuver of the switching apparatus, wherein the opening springs are configured to provide actuation forces directed to move the movable contacts from the coupled position to the uncoupled position, during an opening maneuver of the switching apparatus.
